(19) United States
(12) Patent Application Publication
(10) Pub. No.: US 2003/0211701 A1
(43) Pub. Date: Nov. 13, 2003

(54) Semiconductor device including an isolation trench having a dopant barrier layer formed on a sidewall thereof and a method of manufacture therefor

(75) Inventors: John C. Desko, Wescosville, PA (US); Thomas J. Krutsick, Fleetwood, PA (US); Chung-Ming Hsieh, Wyomissing, PA (US); Brian E. Thompson, Sinking Spring, PA (US); Bailey Jones, Mohnton, PA (US); Steve Wallace, Fleetwood, PA (US)

Correspondence Address: HITT GAINES P.C., P.O. BOX 832570, RICHARDSON, TX, 75083, US

(73) Assignee: Agere Systems Inc., Allentown, PA

(21) Appl. No.: 10/140,558

(22) Filed: May 7, 2002

(51) Int. Cl. H01L 21/76

(52) U.S. Cl. 438/424

(57) ABSTRACT

The present invention provides a semiconductor device, a method of manufacture therefor, and an integrated circuit including the same. In one advantageous embodiment the semiconductor device includes a doped layer located over a semiconductor substrate and an isolation trench located in the doped layer. The isolation trench may further include a bottom surface and a sidewall. Additionally, the semiconductor device may include a dopant barrier layer located on the sidewall and a doped region located in the bottom surface.

### TECHNICAL FIELD OF THE INVENTION

The present invention is directed, in general, to a semiconductor device and, more specifically, to a semiconductor device having an isolation trench with a dopant barrier layer formed on a sidewall thereof, a method of manufacture therefor, and an integrated circuit including the same.

### BACKGROUND OF THE INVENTION

Integrated circuits are well known and are extensively used in various present day technological devices and systems, such as sophisticated telecommunications and computer systems of all types. As the use of integrated circuits continues to grow, the demand for more inexpensive and improved integrated circuits also continues to rise. Thus, presently, an emphasis in the integrated circuit industry is to provide reliable, faster devices at a competitive price.

Deep trench-isolated bipolar transistors are some of the above-mentioned devices wherein there is currently an emphasis placed upon increasing both speed and reliability. In an attempt to increase the speed and reliability of the deep trench-isolated bipolar transistors, the manufacturers of such devices have begun forming a doped structure in the bottom of the isolation trench. In one example, the doped structure is designed to substantially reduce a leakage component between the various MOS devices of the integrated circuit. For example, the doped structure may be placed in such a position to substantially reduce the amount of leakage that occurs between two adjacent npn bipolar transistors. Likewise, the doped structure may also be placed in such a position as to substantially reduce the amount of leakage that occurs between an npn bipolar transistor and an adjacent PNP bipolar transistor.

A problem arises, however, in the manufacture of the doped structure. For example, an implantation step is generally used to form the doped structure within the bottom of the trench. During the implantation step, however, the dopant species used to form the doped structure often counter dopes the sidewalls of the trench. As a result of the trench sidewall counter doping, the deep trench-isolated bipolar transistors experience significant degradation of device performance.

The negative effects associated with the counter doping of the trench sidewalls are most common in vertical pnp bipolar transistors. In such situations, the trench sidewalls are at least partially formed within an n-isolation tub, and the counter doping of the trench sidewalls causes the n-type dopant of the n-isolation tub to be overcome by the p-type counter dopant. While this is particularly evident in vertical pnp bipolar transistors, it may also be expereinced in other semiconductor devices.

Various approaches have been undertaken to reduce the effects associated with the counter doping of the trench sidewalls. One approach includes increasing the dopant concentration of the previously mentioned isolation tub to a value great enough that the counter doping does not convert the trench sidewalls to an oppositely doped material. This increased isolation tub doping, however, tends to degrade device performance.

Another approach includes reducing the implant dose used to form the doped structure. In effect, by reducing the implant dose, the trench sidewall will not easily be counter doped. This approach works, however, the process margin for the implant dose is small. For example, the dose needs to be high enough to prevent MOS inversion, however, low enough to prevent counter doping of the trench sidewall.

Accordingly, what is needed in the art is a semiconductor device and a method of manufacture therefor that does not experience the problems experienced by the prior art semiconductor devices.

### SUMMARY OF THE INVENTION

To address the above-discussed deficiencies of the prior art, the present invention provides a semiconductor device, a method of manufacture therefor, and an integrated circuit including the same. In one advantageous embodiment, the semiconductor device includes a doped layer located over a semiconductor substrate and an isolation trench located in the doped layer. The isolation trench may include a bottom surface and a sidewall. Additionally, the semiconductor device may include a dopant barrier layer located on the sidewall and a doped region located in the bottom surface.

The foregoing has outlined, preferred and alternative features of the present invention so that those skilled in the art may better understand the detailed description of the invention that follows. Additional features of the invention will be described hereinafter that form the subject of the claims of the invention. Those skilled in the art should appreciate that they can readily use the disclosed conception and specific embodiment as a basis for designing or modifying other structures for carrying out the same purposes of the present invention. Those skilled in the art should also realize that such equivalent constructions do not depart from the spirit and scope of the invention.

### BRIEF DESCRIPTION OF THE DRAWINGS

The invention is best understood from the following detailed description when read with the accompanying FIGUREs. It is emphasized that in accordance with the standard practice in the semiconductor industry, various features are not drawn to scale. In fact, the dimensions of the various features may be arbitrarily increased or reduced for clarity of discussion. Reference is now made to the following descriptions taken in conjunction with the accompanying drawings, in which:

FIG. 1 illustrates one embodiment of a semiconductor device constructed in accordance with the principles of the present invention;

FIG. 2 illustrates a partially completed semiconductor device in accordance with the principles of the present invention;

FIG. 3 illustrates the partially completed semiconductor device illustrated in FIG. 2, after formation of isolation trenches;

FIG. 4 illustrates the partially completed semiconductor device illustrated in FIG. 3, after formation of a blanket layer of dopant barrier material;

FIG. 5 illustrates the partially completed semiconductor device illustrated in FIG. 4, after removal of the dopant barrier material from an epitaxial layer surface and a bottom surface of the isolation trenches;

FIG. 6 illustrates the partially completed semiconductor device illustrated in FIG. 5, after formation of doped regions in accordance with the principles of the present invention;

FIG. 7 illustrates the partially completed semiconductor device illustrated in FIG. 6, after formation of a fill material within the isolation trenches; and

FIG. 8 illustrates an integrated circuit in accordance with the principles of the present invention.

### DETAILED DESCRIPTION

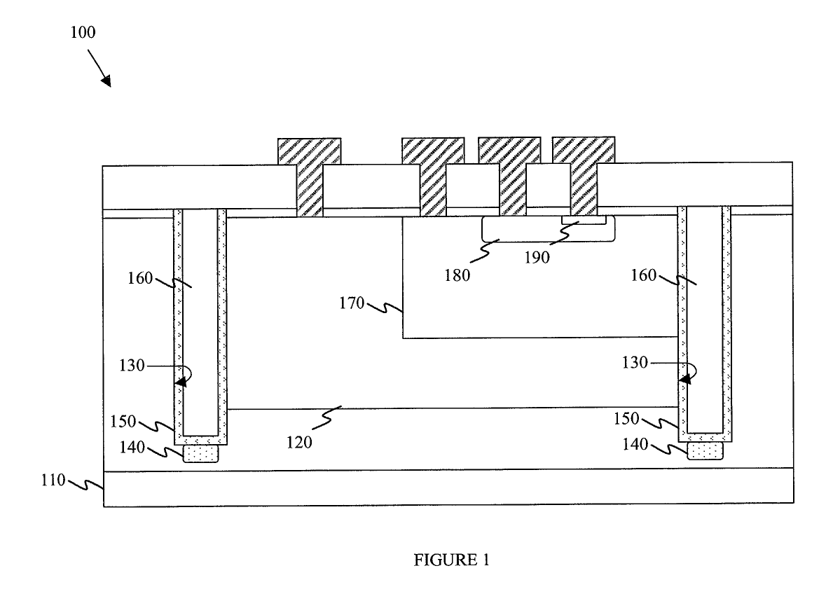

Referring initially to FIG. 1 illustrated is one embodiment of a semiconductor device, generally designated 100, constructed in accordance with the principles of the present invention. In the particular embodiment shown in FIG. 1, the semiconductor device 100 is a vertical pnp bipolar transistor. It should be noted, however, that the semiconductor device 100 may comprise various other devices while staying within the scope of the present invention.

As shown in FIG. 1, the semiconductor device 100 may include a doped layer 120 formed over a semiconductor substrate 110. In the illustrative embodiment shown, the doped layer 120 is an n-isolation tub for the vertical pnp bipolar transistor. One skilled in the art understands, however, that the doped layer 120 may be any doped layer located within the semiconductor device 110. In an alternative embodiment, not shown, a buried layer may be located between the doped layer 120 and the semiconductor substrate 110.

Located at least partially within the doped layer 120 is an isolation trench 130, the isolation trench 130 having a bottom surface and sidewalls. As illustrated, the isolation trench 130 may extend entirely through the doped layer 120. Alternatively, however, the isolation trench may only extend partially through the doped layer 120.

As further illustrated in FIG. 1, a doped region 140 may be formed in the bottom surface of the isolation trench 130. The doped region 140, which in the particular embodiment shown is a p-type doped region, attempts to substantially reduce MOS inversion at the bottom of the trench. In an advantageous embodiment, the reduced MOS inversion substantially decreases the amount of leakage current that occurs between the various devices of the semiconductor device 100.

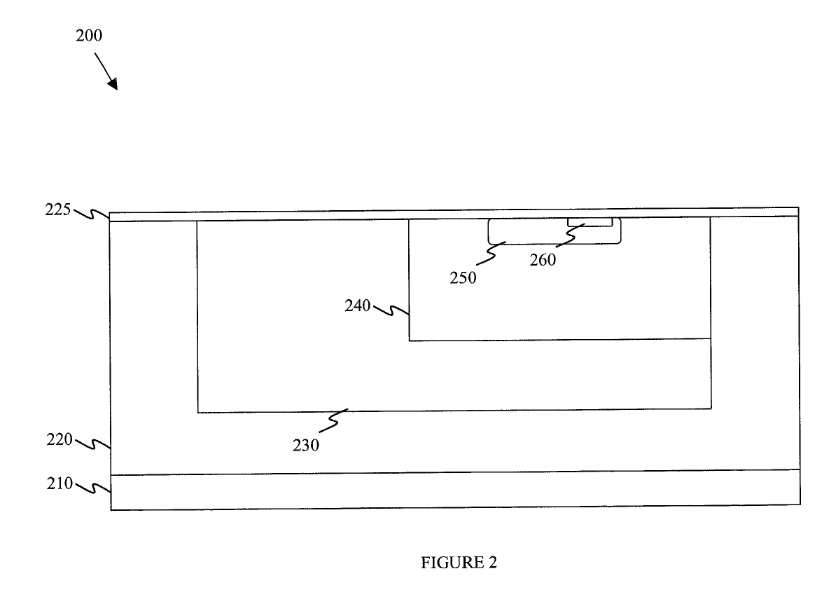

Advantageously formed on the sidewall of the isolation trench 130 is a dopant barrier layer 150. In the present embodiment shown, a portion of the dopant barrier layer 150 is located on the bottom surface of the isolation trench 130. While it has been shown that the portion of the dopant barrier layer 150 is located on the bottom surface of the isolation trench 130, in an alternative embodiment such as that shown in FIGS. 2-7, the dopant barrier layer 150 may be removed from the bottom surface of the isolation trench 130.

Because the dopant barrier layer 150 may be formed prior to the doped region 140, the dopant barrier layer 150 reduces the amount of counter doping caused by the formation of the doped region 140, on the sidewall of the isolation trench 130. In a preferred embodiment of the present invention, the dopant barrier layer 150 substantially eliminates any counter doping of the sidewall of the isolation trench 130. Because the counter doping is reduced, if not substantially eliminated, the semiconductor device 100 does not experience many of the device performance issues experienced by the prior art devices. Additionally, the dopant barrier layer 150 allows for a wide range of doped region 140 implant conditions, while still being able to protect the sidewalls from being significantly counter doped.

The semiconductor device 100 illustrated in FIG. 1, further includes a fill material 160 located over the doped region 140 and dopant barrier layer 150, as well as within the isolation trench 130. Additionally, located within the doped layer 120 is a collector 170, a base 180 and an emitter 190. While specific features of the semiconductor device 100 have been discussed other features that are not shown nor discussed are, nonetheless, within the scope of the present invention. It should be noted that while the present invention has been illustrated using a conventional bipolar transistor, the novel features of the present invention are applicable to a number of different semiconductor devices, including a number of different bipolar devices not shown.

Turning now to FIGS. 2-7, illustrated are detailed manufacturing steps depicting how one skilled in the art might manufacture the semiconductor device 100 illustrated in FIG. 1. FIG. 2 illustrates a partially completed semiconductor device 200 in accordance with the principles of the present invention. In the particular embodiment shown in FIG. 2, the semiconductor device 200 is a vertical pnp bipolar transistor. It should be noted, however, that while the remainder of the discussion will be with respect to the vertical pnp bipolar transistor, the novel aspects of the present invention may be used with any type of semiconductor device 200.

In the illustrative embodiment shown in FIG. 2, the semiconductor device 200 includes an epitaxial layer 220 located over a semiconductor substrate 210. The semiconductor substrate 210 may include any layer located in a semiconductor device 200, including a layer located at or anywhere above wafer level. The epitaxial layer 220 may be a conventional doped epitaxial layer. Further located over the epitaxial layer 220 is an optional oxide layer 225. The optional oxide layer 225 attempts to provide electrical isolation between the various layers in the semiconductor device 200. In an exemplary embodiment, this optional oxide layer 225 is a conventionally formed sacrificial field oxide layer.

The semiconductor device 200 illustrated in FIG. 2 further includes doped layer 230 formed over the semiconductor substrate 210, as well as within the epitaxial layer 220. In an exemplary embodiment, the doped layer 230 is an n-isolation tub for the vertical pnp bipolar transistor. The doped layer 230 may be formed using various conventional techniques, including using photoresist and a high energy implant to drive an n-type dopant, such as phosphorous, into the epitaxial layer 220. In an exemplary embodiment of the present invention, the doped layer 230 has a dopant concentration ranging from about 1E15 atoms/cm³ to about 2E16 atoms/cm³.

The partially completed semiconductor device 200 illustrated in FIG. 2 additionally includes a collector 240, a base 250, and an emitter 260. Similar to the doped layer 230, the collector 240, base 250 and emitter 260 may be formed using various conventional manufacturing techniques. In an exemplary embodiment of the present invention, the collector 240 is doped with a p-type dopant to a concentration ranging from about 3E15 atoms/cm³ to about 2E19 atoms/cm³. Additionally, the base 250 may be doped with an n-type dopant to a concentration ranging from about 1E16 atoms/cm³ to about 5E18 atoms/cm³, and the emitter may be doped with a p-type dopant to a concentration ranging from about 5E18 atoms/cm³ to about 1E20 atoms/cm³. Similar to many conventional vertical pnp bipolar transistors, the base 250 is formed within the collector 240, as well as the emitter 260 is formed within the base 250. While certain details have been give with respect to the manufacture of the semiconductor device 200 thus far, one skilled in the art understands that such steps are conventional.

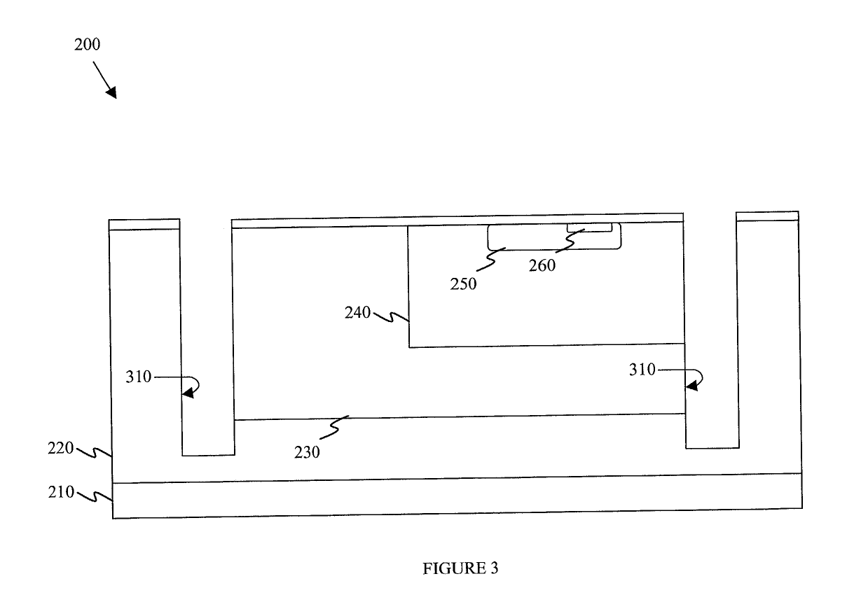

Turning now to FIG. 3, illustrated is the partially completed semiconductor device 200 illustrated in FIG. 2, after formation of isolation trenches 310. In the exemplary embodiment shown, the isolation trenches 310 are formed through the doped layer 230, and may have a width ranging from about 800 nm to about 1300 nm and a depth ranging from about 5000 nm to about 8000 nm. Other locations, widths and depths are, however, within the scope of the present invention. It should be noted that conventional techniques may be used to form the isolation trenches 310, including using photoresist and a wet or dry etching process.

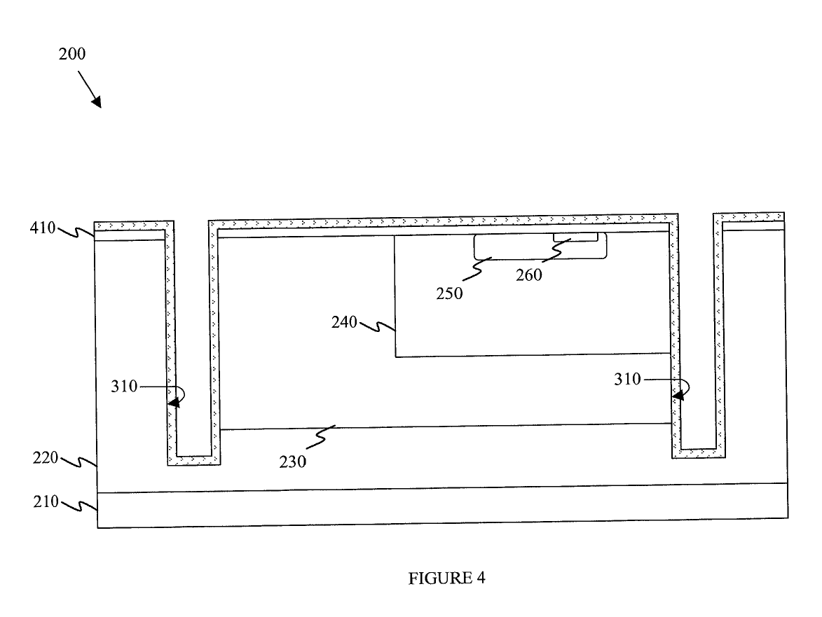

Turning to FIG. 4, illustrated is the partially completed semiconductor device 200 illustrated in FIG. 3, after formation of a blanket layer of dopant barrier material 410. As shown, the dopant barrier material 410 may be located on the surface of the epitaxial layer 220, as well as along the sidewall and bottom surface of the isolation trenches 310. As also shown, the layer of dopant barrier material 410 may comprise a single layer. It should be noted, however, that the layer of dopant barrier material 410 may comprise multiple layers (not shown), each layer having a specific function. For example, one layer could be an adhesion layer.

In the illustrative embodiment shown in FIG. 4, the dopant barrier material 410 comprises an oxide. Alternatively, however, the dopant barrier material may comprise a material selected from the group of materials consisting of silicon dioxide, silicon nitride, silicon oxynitride, low-dielectric constant materials (e.g., those have a dielectric constant less than or equal to about 2.0), as well as various other dopant barrier materials.

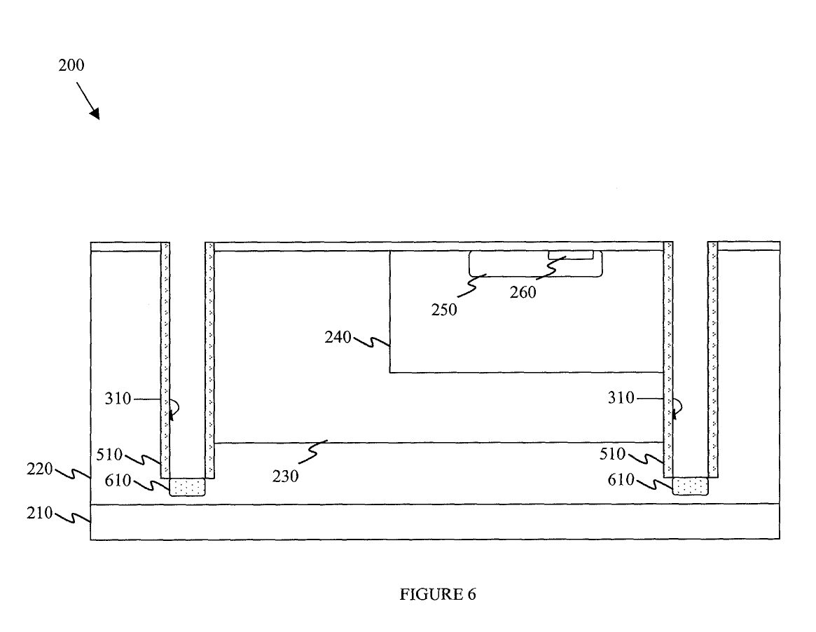

The dopant barrier material 410 may be formed using various well-known processes, depending on the particular material chosen. For example, if the dopant barrier material 410 is an oxide, the oxide may be either thermally grown and/or deposited using a chemical vapor deposition (CVD) process from TEOS or another vapor reactant. The dopant barrier material 410 may, additionally, be formed having various thicknesses. While the dopant barrier material 410 thickness is very much dependent on the dopant dose used to form the doped region (FIG. 6), in an exemplary embodiment shown, the thickness of the dopant barrier material 410 ranges from about 10 nm to about 500 nm.

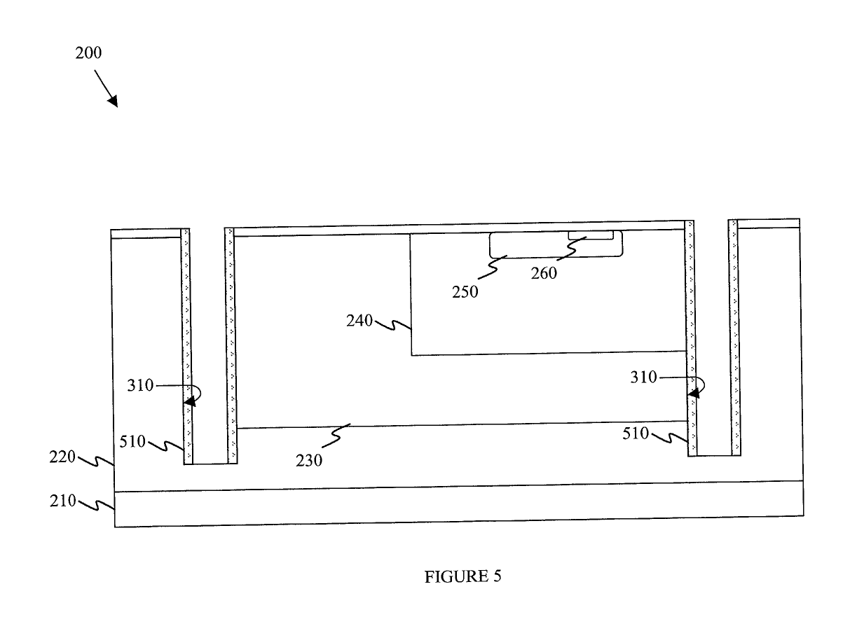

Turning now to FIG. 5, illustrated is the partially completed semiconductor device 200 illustrated in FIG. 4, after removal of the dopant barrier material 410 from the epitaxial layer 220 surface and the bottom surface of the isolation trenches 310. This removal step leaves a dopant barrier layer 510 on the sidewall of the isolation trenches 310. In an exemplary embodiment, the dopant barrier material 410 is removed using a conventional anisotropic etch, using for example, a plasma etch or reactive ion etching (RIE) system. By suitably tailoring the conditions of the anisotropic etch, etching mainly occurs at the bottom surface of the isolation trenches 310 and/or top surface of the epitaxial layer 220, as compared to at the sidewall of the isolation trenches 310. The net result of the anisotropic etch is that the dopant barrier layer 510 remaining on the sidewall, and is thick enough to substantially prevent any counter doping of the isolation trench 310 sidewalls.

While it has been illustrated in this embodiment that the dopant barrier material 410 is completely removed from the bottom surface of the isolation trenches 310, an alternative embodiment of the present invention (as shown in FIG. 1) provides that at least a portion of the dopant barrier material 410 remain on the bottom surface of the isolation trenches 310. In an alternative embodiment of the present invention, in addition to the remaining material, an additional layer of barrier material may be redeposited or regrown in the bottom of the isolation trench 310. In such embodiments, the regrown portions may have a thickness ranging from about 30 nm to about 100 nm.

Turning now to FIG. 6, illustrated is the partially completed semiconductor device 200 illustrated in FIG. 5, after formation of doped regions 610 in accordance with the principles of the present invention. As shown, the doped regions 610 are located “in” the bottom surfaces of the isolation trenches 310. The term “in” as used in this particular instance, means that the doped regions 620 may be formed either within the epitaxial layer 220 (as shown) or on the epitaxial layer 220 (not shown), however, they need be “in” the bottom surface of the isolation trenches 310. The doped regions 610 may, in an exemplary embodiment, have a thickness ranging from about 100 nm to about 200 nm.

The doped regions 610 may be formed using conventional techniques. For example, in one embodiment of the invention, the doped regions 610 are formed by implanting a p-type dopant to a concentration ranging from about 1E17 atoms/cm³ to about 1E20 atoms/cm³. In one exemplary embodiment, the dopant implantation is conducted at a power ranging from about 10 KeV to about 50 KeV.

Because the dopant barrier layer 510 is located on the sidewall of the isolation trenches 310, as discussed above, the dopant implant used to form the doped regions 610 does not substantially counter dope the sidewalls of the isolation trenches 310. If a portion of the dopant barrier layer 510 remains on the bottom surface of the isolation trenches 310, or in an alternative embodiment is added to the bottom surface of the isolation trench 310 as described above, the dopant implant has enough energy to l make it through the portion of the dopant barrier layer 510, however not enough energy to make it through the dopant barrier layer 510 in the sidewall of the isolation trenches 310.

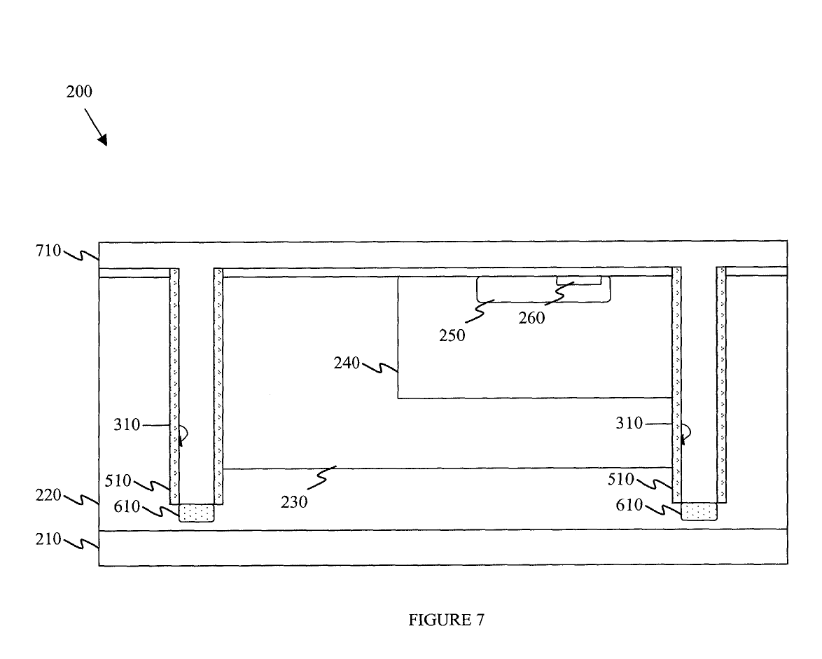

Turning now to FIG. 7, illustrated is the partially completed semiconductor device 200 illustrated in FIG. 6, after formation of a fill material 710 within the isolation trenches 310. In the illustrative embodiment shown, the fill material 710 is conformally deposited over the epitaxial layer 220 as well as over dopant barrier layer 510. The fill material 710 may comprise various conductive and dielectric materials. For example, in the illustrative embodiment shown, the fill material comprises doped polysilicon. After formation of the fill material 710, the semiconductor device 200 may be subjected to a conventional chemical mechanical polishing (CMP) process, resulting in a device similar to the semiconductor device 100 illustrated in FIG. 1.

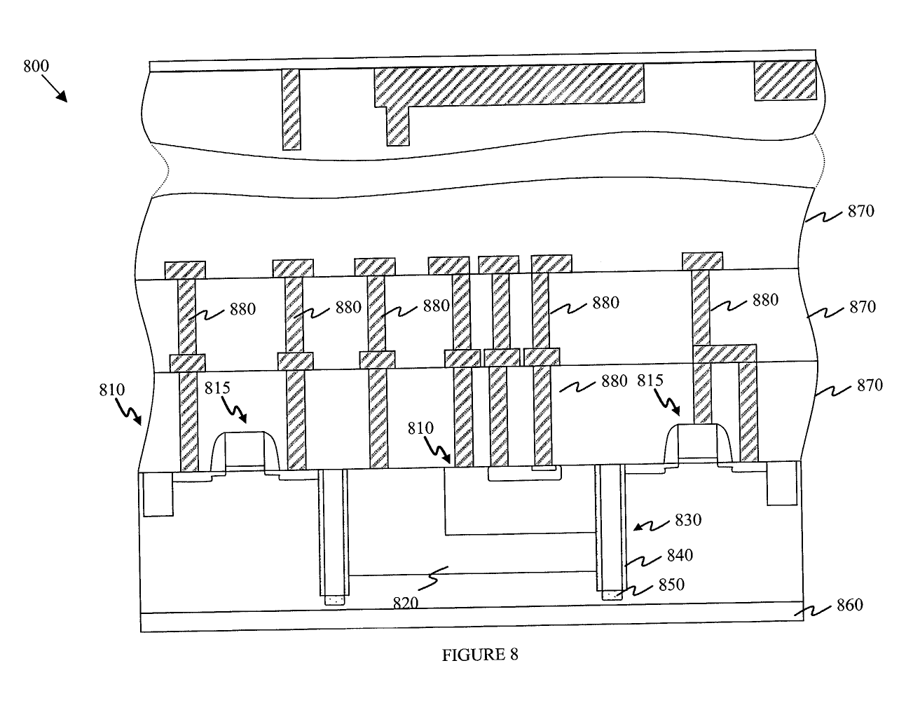

Referring finally to FIG. 8, illustrated is a sectional view of a conventional integrated circuit (IC) 800, incorporating a semiconductor device 810 similar to the completed semiconductor device 100 illustrated in FIG. 1. The IC 800 may also include active devices, such as Bipolar devices, BiCMOS devices, memory devices, or other types of active devices. The IC 800 may further include passive devices, such as inductors or resistors, or it may also include optical devices or optoelectronic devices. Those skilled in the art are familiar with these various types of devices and their manufacture.

In the particular embodiment illustrated in FIG. 8, the IC 800 includes a semiconductor device 810, which are in the form of vertical pnp bipolar transistors, as well as MOS devices 815. As illustrated, the semiconductor device 810 includes a doped layer 820, isolation trenches 830 having a dopant barrier layer 840 formed on their sidewalls, and doped regions 850 located in the bottom surfaces of the isolation trenches 830. As illustrated, all of the aforementioned elements are located over a semiconductor substrate 860. The IC 800 further includes dielectric layers 870 located over the semiconductor device 810 and MOS devices 815. Additionally, interconnect structures 880, are located within the dielectric layers 870, contacting the semiconductor device 810 and MOS devices 815 to form the operational integrated circuit 800.

Although the present invention has been described in detail, those skilled in the art should understand that they can make various changes, substitutions and alterations herein without departing from the spirit and scope of the invention in its broadest form.

What is claimed is:

1. A semiconductor device, comprising:
a doped layer located over a semiconductor substrate;
an isolation trench located in the doped layer, wherein the isolation trench has a bottom surface and a sidewall; and
a dopant barrier layer located on the sidewall; and
a doped region located in the bottom surface.

2. The semiconductor device as recited in claim 1 wherein the dopant barrier layer has a thickness ranging from about 10 nm to about 500 nm.

3. The semiconductor device as recited in claim 1 wherein the dopant barrier layer comprises a material selected from the group consisting of silicon dioxide, silicon nitride, silicon oxynitride or a low dielectric constant material.

4. The semiconductor device as recited in claim 1 further including a fill material, wherein the fill material is doped polysilicon or a dielectric.

5. The semiconductor device as recited in claim 1 wherein a portion of the dopant barrier layer is located on the bottom surface, and the doped region is located thereunder.

6. The semiconductor device as recited in claim 5 wherein the portion has a thickness ranging from about 10 nm to about 100 nm.

7. The semiconductor device as recited in claim 1 wherein the doped region has a dopant concentration ranging from about 1E17 atoms/cm³ to about 1E20 atoms/cm³.

8. A method of manufacturing a semiconductor device, comprising:
providing a doped layer over a semiconductor substrate;
creating an isolation trench in the doped layer, wherein the isolation trench has a bottom surface and a sidewall; and
forming a dopant barrier layer on the sidewall; and
introducing a doped region in the bottom surface.

9. The method as recited in claim 8 wherein forming a dopant barrier layer includes forming a dopant barrier layer having a thickness ranging from about 10 nm to about 500 nm.

10. The method as recited in claim 8 wherein forming a dopant barrier layer includes forming a dopant barrier layer comprising a material selected from the group consisting of silicon dioxide, silicon nitride, silicon oxynitride or a low dielectric constant material.

11. The method as recited in claim 8 further including forming a fill material over the dopant barrier layer and within the isolation trench.

12. The method as recited in claim 11 wherein forming a fill material includes forming doped polysilicon or a dielectric over the dopant barrier layer and within the isolation trench.

13. The method as recited in claim 8 wherein forming a dopant barrier layer includes forming at least a portion of the dopant barrier layer on the bottom surface, and wherein the doped region is located thereunder.

14. The method as recited in claim 13 wherein forming at least a portion of the dopant barrier layer on the bottom surface, includes forming at least a portion having a thickness ranging from about 10 nm to about 100 nm.

15. The method as recited in claim 8 wherein introducing a doped region includes introducing a doped region having a dopant concentration ranging from about 1B17 atoms/cm³ to about 1E20 atoms/cm³.

16. The method as recited in claim 8 wherein forming a dopant barrier layer on the sidewall includes forming a blanket layer of barrier material on the sidewall and the bottom surface, and subsequently removing at least a portion of the dopant barrier layer located on the bottom surface using an anisotropic etch.

17. The method as recited in claim 8 wherein forming a dopant barrier layer includes growing a dopant barrier layer on the sidewall.

18. An integrated circuit, comprising:
a doped layer located over a semiconductor substrate;
an isolation structure, including;
an isolation trench located in the doped layer, wherein the isolation trench has a bottom surface and a sidewall; and
a dopant barrier layer located on the sidewall; and
a doped region located in the bottom surface;
transistors located over the doped layer; and
interconnects located within interlevel dielectric layers located over the transistors, which connect the transistors to form an operational integrated circuit.

19. The integrated circuit as recited in claim 18 wherein a portion of the dopant barrier layer is located on the bottom surface, and the doped region is located thereunder.

20. The integrated circuit as recited in claim 18 wherein the isolation structure is located between a bipolar and a non-bipolar transistor.
